(19) United States
(12) Patent Application Publication
(10) Pub. No.: US 2012/0170999 A1
(43) Pub. Date: Jul. 5, 2012

(54) LOAD LOCK DEVICE AND PROCESSING SYSTEM

(75) Inventor: Hiromitsu Sakaue, Nirasaki-shi (JP)

(73) Assignee: TOKYO ELECTRON LIMITED, Tokyo (JP)

(21) Appl. No.: 13/392,656

(22) PCT Filed: Aug. 23, 2010
(86) PCT No.: PCT/JP2010/064194

§ 371 Date: Feb. 27, 2012

(30) Foreign Application Priority Data
Aug. 29, 2009 (JP) 2009-199103

(51) Int. Cl. H01L 21/677; F27D 3/00

(52) U.S. Cl. 414/160; 414/217

(57) ABSTRACT

A load lock device is connected between a vacuum chamber and an atmospheric chamber through gate valves and the interior thereof is selectively switchable between a vacuum atmosphere and an atmospheric pressure atmosphere. The load lock device includes: a load lock container; a support unit provided in the load lock container and having supporting portions for supporting target objects in multiple stages; a gas introduction unit having gas ejection holes which are provided so as to correspond to the supporting portions and eject as a cooling gas a restoring as for restoring the atmosphere in the load lock container to the atmospheric pressure; and a vacuum exhaust system for evacuating the atmosphere in the load lock container to vacuum.

### FIELD OF THE INVENTION

The present invention relates to a processing system for processing a target object such as a semiconductor wafer or the like, and a load lock device used for the same.

### BACKGROUND OF THE INVENTION

Generally, in order to manufacture semiconductor devices, various processes such as a film forming process, an oxidation/diffusion process, a modification process, an etching process, an annealing process and the like are repeatedly performed on a semiconductor wafer. A so-called cluster tool type processing system disclosed in, e.g., Japanese Patent Application Publication Nos. 2007-27378 and 2007-194582, is known as a system capable of effectively performing such various processes. This processing system includes a common transfer chamber that can be maintained at a vacuum atmosphere, and a plurality of single wafer processing apparatuses connected to the common transfer chamber. A semiconductor wafer is sequentially transferred to the processing apparatuses via the common transfer chamber, and a predetermined process is carried out in each of the processing apparatuses.

In this processing system, one or more small capacity load lock devices, whose interiors can be selectively switched between a vacuum atmosphere and an atmospheric pressure atmosphere, are connected to the common transfer chamber. Moreover, the inside of the load lock device is selectively set between the vacuum atmosphere and the atmospheric pressure atmosphere in order to load and unload the semiconductor wafer between the common transfer chamber in a vacuum atmosphere and the external environment of a substantially atmospheric pressure. Accordingly, the semiconductor wafer is loaded and unloaded without breaking the vacuum atmosphere in the common transfer chamber. Here, the load lock device has a cooling mechanism, e.g., a cooling plate or the like, capable of cooling the semiconductor wafer heated to a high temperature by heat treatment in the processing apparatus to a stable temperature, e.g., about 100° C. Therefore, the semiconductor wafer can be taken out to the outside after being cooled to a temperature lower than or equal to about 100° C.

In the above processing system, it is assumed that each of the processing apparatuses is configured as a so-called single wafer processing apparatus. However, recently, there is proposed a processing system including processing apparatuses for processing a plurality of, e.g., about 4 to 25, semiconductor wafers at a time.

In that case as well, if a plurality of, e.g., 4 to 25, semiconductor wafers are simultaneously subjected to heat treatment at a high temperature, e.g., about 150° C. to 700° C., in the processing apparatus, the semiconductor wafers need to be unloaded after being cooled to a stable temperature lower than or equal to about 100° C.

However, a conventional load lock device is configured to cool a single semiconductor wafer at a time. In other words, it is not possible to cool a plurality of semiconductor wafers at a time, so that a throughput is decreased. Therefore, there is suggested in, e.g., Japanese Patent Application Publication No. 2003-332323, a load lock chamber in which semiconductor wafers are supported in multiple stages. However, the load lock chamber disclosed in Japanese Patent Application Publication No. 2003-332323 serves to allow a semiconductor wafer in a nonreactive gas atmosphere to be exposed to the atmosphere, and thus cannot be used as a load lock chamber for loading and unloading a semiconductor wafer between a vacuum atmosphere and an atmospheric pressure atmosphere.

### SUMMARY OF THE INVENTION

In view of the above, the present invention provides a load lock device and a processing system which can maintain a high throughput by increasing cooling efficiency and can uniformly cool target objects in multiple stages without an temperature difference therebetween.

In accordance with a first aspect of the present invention, there is provided a load lock device adapted to be connected between a vacuum chamber and an atmospheric chamber through gate valves, the interior of the load lock device being selectively switchable between a vacuum atmosphere and an atmospheric pressure atmosphere, the load lock device including: a load lock container; a support unit provided in the load lock container and having supporting portions for supporting target objects in multiple stages; a gas introduction unit having gas ejection holes which are provided so as to correspond to the supporting portions and eject as a cooling gas a restoring gas for restoring the atmosphere in the load lock container to the atmospheric pressure; and a vacuum exhaust system for evacuating the atmosphere in the load lock container to vacuum.

In accordance with a second aspect of the present invention, there is provided a processing system including: a vacuum chamber connected to a processing chamber for performing heat treatment on a plurality of target objects at a time, the vacuum chamber serving as a vacuum transfer chamber having therein a vacuum transfer mechanism for transferring the target objects; an atmospheric chamber whose interior is maintained at or around an atmospheric pressure, the atmospheric chamber serving as an atmospheric transfer chamber including therein an atmospheric transfer mechanism for transferring the target objects to load or unload the target objects with respect to atmospheric side; and the load lock device described in claim 1, provided between the vacuum chamber and the atmospheric chamber.

In accordance with a third aspect of the present invention, there is provided a processing system including: a vacuum chamber serving as a processing chamber for performing heat treatment on a plurality of target objects at a time; an atmospheric chamber whose interior is maintained at or around an atmospheric pressure, the atmospheric chamber serving as an atmospheric transfer chamber including therein an atmospheric transfer mechanism for transferring the target objects to load or unload the target objects with respect to atmospheric side; and the load lock device described in claim 14, provided between the vacuum chamber and the atmospheric chamber.

### BRIEF DESCRIPTION OF THE DRAWINGS

FIG. 1 is a schematic diagram showing an example of a processing system having a load lock device in accordance with an embodiment of the present invention.

FIG. 2 is a vertical cross sectional view showing the load lock device.

FIG. 3 is an enlarged partial cross sectional view of a support unit for supporting target objects.

FIG. 4 is a top view showing an example of supporting portions of the support unit.

FIG. 5 is an enlarged view showing a cross section of a support unit of a first modification of the load lock device.

FIG. 6 is an enlarged partial cross sectional view showing a support unit of a second modification of the load lock device.

FIG. 7 is a schematic top view showing an example of a processing system including a third modification of the load lock device.

### DETAILED DESCRIPTION OF THE EMBODIMENTS

A load lock device and a processing system in accordance with embodiments of the present invention can provide the following effects and advantages.

A load lock device, which is connected between a vacuum chamber and an atmospheric chamber through gate valves and whose interior is selectively switched between a vacuum atmosphere and an atmospheric pressure atmosphere, includes a support unit provided in a load lock container and having supporting portions for supporting target objects in multiple stages; and a gas introduction unit having gas ejection holes which are provided so as to correspond to the supporting portions and eject as a cooling gas a restoring gas for restoring the atmosphere in the load lock container to the atmospheric pressure. Therefore, when the target objects are unloaded to the atmospheric chamber, cooling efficiency can be increased to maintain a high throughput. Further, the target objects in multiple stages can be uniformly cooled without a temperature difference therebetween.

Especially, in the case of further providing an atmospheric exhaust system for exposing an atmosphere in the load lock container to the outside, a heated cooling gas can be actively discharged from an upper portion of the load lock container after the atmosphere in the load lock container is returned to the atmospheric pressure. This can further increase the cooling efficiency.

In the case of further providing a temperature measurement unit at the supporting portion and an opening operation restricting unit for restricting an opening operation of the gate valve between the load lock container and the atmospheric chamber based on a measurement value of the temperature measurement unit, the gate valve can be opened after the target objects are cooled to a desired temperature, so that the safety can be increased.

Hereinafter, the load lock device and the processing system in accordance with the embodiments of the present invention will be described with reference to the accompanying drawings.

(Processing System)

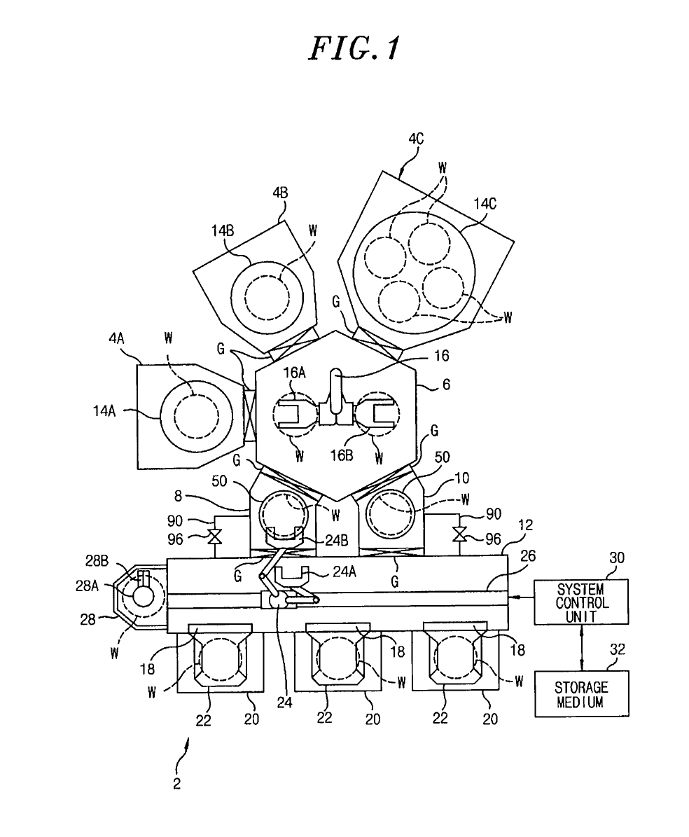

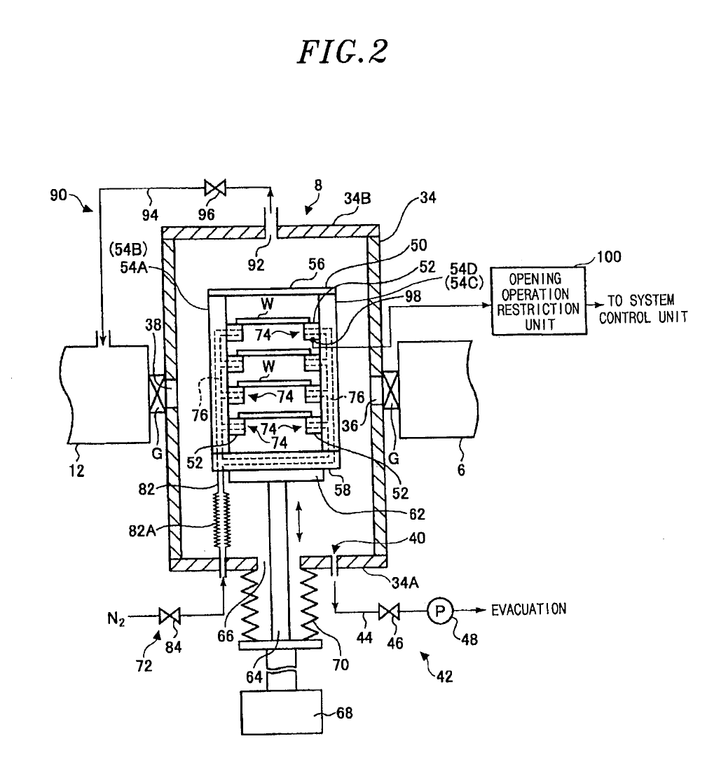

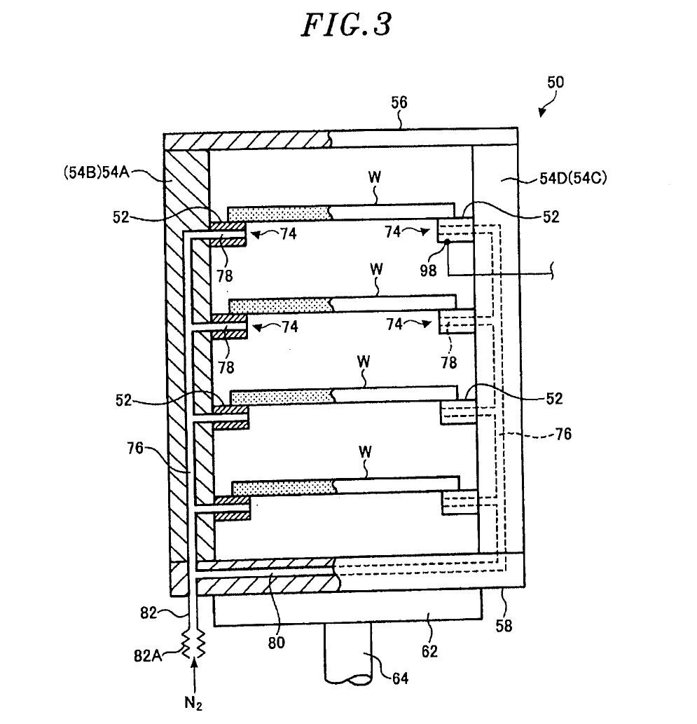

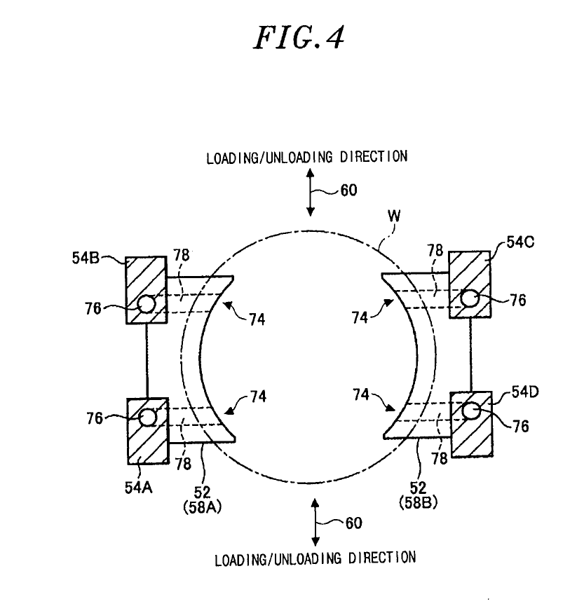

First, a processing system having a load lock device in accordance with the embodiment of the present invention will be described. FIG. 1 is a schematic diagram showing an example of a processing system having a load lock device of the present embodiment. FIG. 2 is a vertical cross sectional view showing the load lock device of the present embodiment. FIG. 3 is an enlarged partial cross sectional view of a support unit for supporting target objects. FIG. 4 is a top view showing an example of supporting portions of the support unit.

As shown in FIG. 1, a processing system 2 mainly includes: a first to a third processing chamber 4A to 4C serving as three vacuum chambers; a substantially hexagonal vacuum transfer chamber 6 serving as a vacuum chamber; load lock devices 8 and 10 in accordance with a first and a second embodiment, each having a load lock function; and an atmospheric transfer chamber 12 serving as an atmospheric chamber having a narrow and long shape.

In this example, among the three processing chambers 4A to 4C, two processing chambers 4A and 4B are configured as single wafer processing chambers in which a single semiconductor wafer W is mounted and processed on each of mounting tables 14A and 14B. On the other hand, the third processing chamber 4C is configured as a so-called batch type processing chamber in which a plurality of, e.g., four in the illustrated example, semiconductor wafers W are mounted on a mounting table 14C and processed simultaneously. The mounting table 14C can rotate in order to maintain the processing uniformity among the semiconductor wafers. In the three processing chambers 4A to 4C, various processes can be performed, when necessary, under a vacuum atmosphere. Especially, in the processing chamber 4C, the semiconductor wafer is subjected to heat treatment such as thermal CVD, thermal diffusion, annealing or the like. The semiconductor wafer W is heated to a temperature ranging from, e.g., about 150° C. to 700° C., depending on types of the processes performed on the semiconductor wafer W.

The first to the third processing chambers 4A to 4C are respectively connected to three sides of the substantially hexagonal vacuum transfer chamber 6, and the first and the second load lock device 8 and 10 are respectively connected to other two sides of the substantially hexagonal vacuum transfer chamber 6. Further, the atmospheric transfer chamber 12 is commonly connected to the sides of the first and the second load lock device 8 and 10 which are opposite to the vacuum transfer chamber 6.

Gate valves G that can be opened and closed airtightly are provided between the vacuum transfer chamber 6 and the three processing chambers 4A to 4C and between the vacuum transfer chamber 6 and the first and the second load lock device 8 and 10. Accordingly, the processing chambers 4A to 4C and the first and the second load lock device 8 and 10 can communicate with the vacuum transfer chamber 6, when necessary. Here, the inside of the vacuum transfer chamber 6 is evacuated to a vacuum atmosphere. Further, gate valves G that can be opened and closed airtightly are also provided between the first and the second load lock device 8 and 10 and the atmospheric transfer chamber 12. As will be described later, the first and the second load lock device 8 and 10 are exhausted to vacuum and returned to an atmospheric pressure in accordance with the loading and unloading operation of the semiconductor wafers.

Besides, a vacuum transfer mechanism 16 configured as a multi-joint arm capable of extending, contracting and rotating is provided in the vacuum transfer chamber 6 so as to access the two load lock devices 8 and 10 and the three processing chambers 4A to 4C. The vacuum transfer mechanism has two picks 16A and 16B capable of independently extending and contracting in opposite directions, so that it can handle two semiconductor wafers at a time. The vacuum transfer mechanism 16 may have a single pick.

The atmospheric transfer chamber 12 is formed in a horizontally elongated box shape. One or more (three in the illustrated example) loading/unloading ports for loading and unloading a semiconductor wafer as a target object are provided at one longitudinal side of the atmospheric transfer chamber 12. Each of the loading/unloading ports is provided with an opening/closing door 18. Inlet ports 20 are provided so as to correspond to the loading/unloading ports, and cassette containers 22 can be mounted thereon. Each of the cassette containers 22 can accommodate therein a plurality of, e.g., 25, semiconductor wafers W at a regular pitch in the vertical direction.

Each of the cassette containers 22 is hermetically sealable and filled with a nonreactive gas such as N₂ gas or the like. The pressure in the atmospheric transfer chamber 12 is maintained at a substantially atmospheric pressure by, e.g., N₂ gas or clean air. Specifically, the pressure in the atmospheric transfer chamber 12 is maintained at an atmospheric pressure or a positive pressure slightly greater by, e.g., about 1.3 Pa than the atmospheric pressure.

Further, an atmospheric transfer mechanism 24 for transferring the semiconductor wafer W along the longitudinal direction of the atmospheric transfer chamber 12 is provided in the atmospheric transfer chamber 12. The atmospheric transfer mechanism 24 has two picks 24A and 24B capable of extending, contracting and rotating, so that it can handle two semiconductor wafers W at a time. The atmospheric transfer mechanism 24 is slidably supported on a guide rail 26 extending along the longitudinal direction of the atmospheric transfer chamber 12.

Moreover, an orienter 28 for position alignment of the semiconductor wafer is provided at one end of the atmospheric transfer chamber 12. The orienter 28 has a rotatable table 28A rotated by a driving motor, and the semiconductor wafer W is mounted and rotated thereon. An optical sensor 28B for detecting a peripheral portion of the semiconductor wafer W is provided at an outer periphery of the rotatable table 28A. Accordingly, a position of a positioning cutout, e.g., a notch or an orientation flat, of the semiconductor wafer W and a positional misalignment amount of the center of the semiconductor wafer W can be detected.

The processing system 2 includes a system control unit 30 having, e.g., a computer or the like, for controlling the entire operation of the system. The program required to control the entire operation of the processing system processing is stored in a storage medium 32 such as a flexible disc, a CD (Compact Disc), a hard disc, a flash memory or the like. Specifically, operations including start and stop of gas supply (opening and closing of the opening/closing valves), flow rate control, control of a process temperature (a temperature of the semiconductor wafer) and a process pressure (a pressure in the processing chamber), opening and closing of the gate valves G, transferring of the semiconductor wafer and the like are carried out in accordance with instructions from the system control unit 30.

(Description of Load Lock Device)

Hereinafter, the load lock devices 8 and 10 will be described with reference to FIGS. 2 to 4. The load lock devices 8 and 10 have the same configuration and operation. Therefore, one load lock device 8 will be described as an example, and description of the other load lock device 10 will be omitted.

As shown in FIG. 2, the load lock device 8 has a vertically elongated load lock container 34. The load lock container 34 has a box shape and is made of metal, e.g., aluminum alloy, stainless steel or the like. A loading/unloading port 36 for loading and unloading the semiconductor wafer W is provided at a middle portion of one side of the load lock container 34, and the vacuum transfer chamber 6 is connected to the loading/unloading port 36 via a gate valve G. Further, a loading/unloading port 38 for loading and unloading the semiconductor wafer W is provided at a middle portion of the other side of the load lock container 34 opposite to the loading/unloading port 36. The vacuum transfer chamber 12 is connected to the loading/unloading port 38 via a gate valve G.

Moreover, a vacuum exhaust port 40 is provided at a bottom portion 34A of the load lock container 34, and a vacuum exhaust system 42 for evacuating the load lock container 34 to vacuum is provided at the vacuum exhaust port 40. Specifically, the vacuum exhaust system 42 has a gas exhaust passage 44 connected to the vacuum exhaust port 40, and an opening/closing valve 46 and a vacuum pump 48 are sequentially installed on the gas exhaust passage 44.

Provided in the load lock container 34 is a support unit 50 having supporting portions 52 for supporting a plurality of semiconductor wafers W as target objects in multiple stages. As shown in FIGS. 3 and 4, the support unit 50 has a plurality of, four in this example, upright columns 54A to 54D arranged in a rectangular array. The upper ends of the four columns 54A to 54D are connected to a top plate 56 as one body, and the lower ends of the four columns 54A to 54D are connected to a bottom plate 58 as one body. The columns 54A and 54C are spaced apart from each other at an interval slightly larger than the diameter of the semiconductor wafer W such that the semiconductor wafer W can be positioned therebetween. The columns 54B and 54D are also spaced apart from each other at an interval slightly larger than a diameter of the semiconductor wafer W so as to allow the semiconductor wafer W to be positioned therebetween.

Besides, the supporting portions 52 are attached to the columns 54A to 54D in multiple stages, i.e., four stages, at a predetermined pitch in the longitudinal direction of the columns 54A to 54D. Four semiconductor wafers W can be held on the supporting portions 52. Here, each of the supporting portions 52 includes a pair of shelf members 58A and 58B facing each other. One shelf member 58A is horizontally fixed to the two columns 54A and 54B to bridge over them, and the other shelf member 58B is horizontally fixed to the two columns 54C and 54D to bridge over them.

Further, the facing portions of the shelf members 58A and 58B are formed in circular arc shapes conforming to the circumference of the semiconductor wafer W. The semiconductor wafer W is mounted and supported on the shelf members 58A and 58B such that the backside (bottom surface) of the peripheral portion of the semiconductor wafer W comes into contact with the top surfaces of the shelf members 58A and 58B. The predetermined pitch between the supporting portions 52 is set to range from, e.g., about 10 mm to about 30 mm, so as to allow the approach of the picks 16A and 16B of the vacuum transfer mechanism 16 and the picks 24A and 24B of the atmospheric transfer mechanism 24 which hold the semiconductor wafers W thereon.

In that case, the picks 16A, 16B, 24A and 24B enter a space between the column 54A or 54B and the column 54D or 54C. Further, a direction indicated by arrows 60 in FIG. 4 becomes a loading/unloading direction. FIG. 4 shows the support unit 50 viewed from 90 degrees away from FIGS. 2 and 3 in order to assist the understanding of the configuration of the present embodiment. Here, the support unit 50 is made of one or more materials selected from the group including ceramic, quartz, metal, heat resistant resin. Specifically, the columns 54A to 54D, the top plate 56 and the bottom plate 58 are preferably made of metal such as aluminum alloy or the like, and the supports 52 which come into direct contact with the semiconductor wafer W are preferably made of a heat resistant material such as quartz, ceramic or the like.

Moreover, the support unit 50 includes a gas introduction unit 72 having gas ejection holes 74 which are provided so as to correspond to the supporting portions 52 and eject as a cooling gas a restoring gas for restoring the atmosphere in the load lock container 34 to the atmospheric pressure. Specifically, the gas introduction unit 72 has gas inlet lines 76 formed in the support unit 50. Here, the gas inlet lines 76 are formed in the four columns 54A to 54D along the longitudinal direction thereof, and gas nozzles 78 are horizontally formed from the gas inlet lines 76 so as to pass through the shelf members 58A and 58B as the supporting portions 52.

Accordingly, the leading ends of the gas nozzles 78 are configured as the gas ejection holes 74. With this configuration, the cooling gas can be ejected in a horizontal direction corresponding to the arrangement direction of the supporting portions 52. In this example, one semiconductor wafer W is cooled by the cooling gas ejected from the four gas ejection holes 74. Further, the number of the gas ejection holes 74 for one semiconductor wafer W is not limited to four, and may be more than or less than four.

A communication path 80 (see FIG. 3) commonly communicating with the four gas inlet lines 76 is formed in the bottom plate 58. The communication path 80 is connected to a gas line 82 airtightly extending through the bottom portion 34A of the load lock container 34 to the outside. Further, an extensible/contractible bellows portion 82A is provided at a part of the gas line 82 positioned in the load lock container 34. The bellows portion 82A can be extended or contracted in accordance with the vertical movement of the support unit 50.

Moreover, an opening/closing valve 84 is provided in the gas line 82 to allow supply of an atmospheric pressure restoring gas as a cooling gas when necessary. As for the atmospheric pressure restoring gas (cooling gas), it is possible to use a rare gas such as He gas, Ar gas or the like, or a nonreactive gas such as N₂ gas or the like. In this example, N₂ gas is used. In this case, if the temperature of the cooling gas is excessively low, the semiconductor wafer in a high temperature state may be damaged by sudden cooling. Therefore, the temperature of the cooling gas needs to be set in accordance with the temperature of the semiconductor wafer to be cooled. For example, the temperature of the cooling gas may be set to a room temperature.

The bottom plate 58 of the support unit 50 configured as described above is installed on the elevation plate 62, so that the support unit 50 can be vertically moved. Specifically, the elevation plate 62 is fixed to the upper end portion of the elevation rod 64 extended through a through hole 66 formed in the bottom portion 34A of the load lock container 34. An actuator 68 is attached to the lower end portion of the elevation rod 64, and is configured to vertically move the elevation rod 64. In this case, the actuator 68 can stop the elevation plate 62 at certain vertical positions in multiple stages corresponding to the positions of the supporting portions 52. Further, an extensible/contractible metallic bellows 70 is attached to the through hole 66 of the elevation rod 64, so that the elevation rod 64 can be vertically moved while maintaining airtightness in the load lock container 34.

Referring to FIG. 2, an atmospheric exhaust system 90 for exposing an atmosphere in the load lock container 34 to the outside is provided in the load lock container 34. Specifically, the atmospheric exhaust system 90 has a gas discharge port 92 formed at an upper portion of the load lock container 34. Here, the gas discharge port 92 is provided at a ceiling portion 34B of the load lock container 34. An atmospheric channel 94 is connected to the gas discharge port 92, and a relief valve 96 is disposed in the atmospheric channel 94. The relief valve 96 is opened when a pressure difference between an inlet and an outlet of the relief valve is greater than a predetermined pressure difference. Hence, the relief valve 96 is opened when a pressure in the load lock container 34 becomes higher than a pressure at a downstream side of the atmospheric channel 94 by a predetermined pressure.

Here, the atmospheric channel 94 communicates with the atmospheric transfer chamber 12 as an atmospheric chamber. Further, the downstream side of the atmospheric channel 94 may be opened to the atmospheric side (a clean room where the processing system 2 is installed). The predetermined pressure difference that allows the relief valve 96 to be opened is set to, e.g., about 1.3 Pa.

A temperature measurement unit, e.g., a thermocouple 98, is provided at the supporting portion 52 of the support unit 50 to measure the temperature of the semiconductor wafer supported by the supporting portion 52. The measurement value of the thermocouple 98 is inputted to an opening operation restriction unit 100 having, e.g., a computer or the like. When a predetermined safe temperature, e.g., about 100° C., is measured by the thermocouple 98, the opening operation restriction unit 100 outputs to the system control unit 30 a signal for permitting opening of the gate valve G of the atmospheric transfer chamber 12. In this example, the thermocouple 98 is provided at the uppermost supporting portion 52 among the supporting portions 52 arranged in multiple stages. However, the thermocouple 98 may be provided at each of the supporting portions 52 except the lowermost supporting portion 52 or may be provided at all the four supporting portions 52. In that case, an opening operation permission signal may be outputted when the temperatures measured by all the thermocouples 98 reach about 100° C. As described above, the second load lock device 10 has the same configuration as that of the first load lock device 10.

(Description of Operation of Processing System and Load Lock Device)

Hereinafter, the operations of the processing system 2 and the load lock devices 8 and 10 having the above-described configurations will be schematically explained. First, an unprocessed semiconductor wafer W, e.g., a silicon substrate, is loaded from the cassette container 22 provided at the inlet port 20 into the atmospheric transfer chamber 12 by the atmospheric transfer mechanism 24. Then, the semiconductor wafer W is transferred to the orienter 28 provided at one end of the atmospheric transfer chamber 12, and position alignment of the semiconductor wafer W is performed in the orienter 28.

After the position alignment is completed, the semiconductor wafer W is transferred into one of the first and the second load lock device 8 and 10 by the atmospheric transfer mechanism 24. By repeating this transfer operation of the semiconductor wafer W four times, four semiconductor wafers W are supported by the support unit 50 in the load lock device. After the inside of the load lock device 8 (10) is evacuated to vacuum, the unprocessed semiconductor wafer W in the load lock device 8 (10) is transferred into the vacuum transfer chamber 16 by the vacuum transfer mechanism 16 in the vacuum transfer chamber 6 which is previously evacuated to vacuum.

The unprocessed semiconductor wafer W is transferred into, e.g., the first and the second processing chamber 4A and 4b sequentially, and predetermined processes are performed in the first and the second processing chamber 4A and 4B. Then, the semiconductor wafer is loaded into the third processing chamber 4C. After the predetermined processes are performed on the four semiconductor wafers W in the above-described order, the four semiconductor wafers W are mounted on the mounting table 14C of the third processing chamber 4C. Next, predetermined heat treatment such as thermal CVD, annealing, thermal oxidation/diffusion or the like is performed in the third processing chamber 4C. The semiconductor wafers W are heated to a temperature ranging from, e.g., about 150° C. to 700° C., depending on types of the processes performed on the semiconductor wafers W.

Upon completion of the predetermined heat treatment in the third processing chamber 4C, the semiconductor wafers W in the high temperature state are sequentially transferred by the vacuum transfer mechanism 16 to the support unit 50 of one of the load lock devices 8 and 10 which is previously maintained in a vacuum state, e.g., the first load lock device 8, and then are supported in multiple stages. Then, the first load lock device 8 is sealed by closing the gate valve G at the side of the vacuum transfer chamber 6, and the four semiconductor wafers W are cooled by introducing N₂ gas as a cooling gas and an atmospheric restoring gas into the load lock device 8.

When the pressure in the load lock device 8 is restored to the atmospheric pressure, the relief valve 96 is opened to obtain a balance with the pressure in the atmospheric transfer chamber 12. When the temperature of the semiconductor wafer W is lower than or equal to about 100° C., the gate valve G at the side of the atmospheric transfer chamber 12 is opened, and the inner space of the load lock device 8 and that of the atmospheric transfer chamber 12 communicate with each other. The four processed semiconductor wafers W in the load lock device 8 are sequentially unloaded by the atmospheric transfer mechanism 24 and returned to the cassette container 22 which accommodates therein processed semiconductor wafers. Thereafter, the same operations are repeatedly carried out.

Hereinafter, the operation in the load lock device 8 will be described in detail. First, the case in which the semiconductor wafer W is transferred between the pick 24A or 24B of the atmospheric transfer mechanism 24 or the pick 16A or 16B of the vacuum transfer mechanism 16 and the support unit 50 of the load lock device 8 will be described. Here, the case of using the pick 16A of the vacuum transfer mechanism 16 will be described as an example.

In order to transfer the semiconductor wafer W held on the pick 16A to one of the supporting portions 52 of the support unit 50, the pick 16A holding the semiconductor wafer W is inserted into a space above the corresponding supporting portion 52. In that state, by driving the actuator 68, the support unit 50 is raised by a predetermined distance. Accordingly, the semiconductor wafer W held on the pick 16A is mounted on the supporting portion 52. Then, the pick 16A is taken out, and the transfer operation is completed.

On the other hand, in order to transfer the semiconductor wafer W held on one of the supporting portions 52 to the pick 16A, the empty pick 16A is inserted to a space below the corresponding supporting portion 52 holding the semiconductor wafer W. Then, by driving the actuator 68, the support unit 50 is lowered by a predetermined distance. Accordingly, the semiconductor wafer W held on the supporting portion 52 is transferred to the pick 16A. Thereafter, the pick 16A holding the semiconductor wafer W is taken out, and the transfer operation is completed. In this example, the pitch between the supporting portions 52 is set to range from about 10 mm to about 30 mm as described above, so that the support unit 50 can be scaled down. Further, the elevation stroke of the support unit 50 can be reduced, and the transfer operation can be performed with a high throughput.

By performing the following operations, the semiconductor wafer W heated to a high temperature by the heat treatment is cooled, and the pressure in the load lock container 34 is returned to an atmospheric pressure. By using the vacuum transfer mechanism 16, the four semiconductor wafers W heated to a high temperature of about 150° C. to 700° C. by the heat treatment in the third processing chamber 4C are held on the supporting portions 52 of the support unit 50 in the load lock container 34 of one of the load lock devices 8 and 10 which is previously maintained in a vacuum state (see FIG. 2).

Then, the inside of the load lock container 34 is airtightly sealed by closing the gate valve G at the side of the vacuum transfer chamber 6. Next, the opening/closing valve 84 of the gas introduction unit 72 is opened, and N₂ gas serving as an atmospheric pressure restoring gas as a cooling gas is introduced at a predetermined flow rate. The introduced N₂ gas flows in the gas inlet lines 76 formed in the columns 54A to 54D of the support unit 50 via the gas line 82, and then is horizontally ejected from the gas ejection holes 74 formed at the leading ends of the gas nozzles 78 communicating with the gas inlet lines 76 to reach the backside of the semiconductor wafer W.

Since the gas ejection holes 74 are provided so as to correspond to the supporting portions 52, the four semiconductor wafers W held on the supporting portions 52 are cooled approximately at the same time by the ejected N₂ gas. In this case, each semiconductor wafer W is cooled by N₂ gas ejected from the four gas ejection holes 74, so that the semiconductor wafer W can be cooled efficiently. Further, since N₂ gas is ejected from the gas ejection holes 74 provided so as to correspond to the supporting portions as described above, the cooling efficiency can be increased, which ensures a high throughput. Moreover, the semiconductor wafers are cooled at the same cooling rate, so that all the semiconductor wafers can be uniformly cooled without a temperature difference between the semiconductor wafers.

In this manner, the semiconductor wafers W are cooled, and the pressure in the load lock container 34 is gradually returned to an atmospheric pressure. When the pressure in the load lock container 34 becomes slightly higher than the atmospheric pressure, the relief valve 96 disposed in the atmospheric channel 94 of the atmospheric exhaust system 90 is opened, and the pressure in the load lock container 34 is decreased to obtain a balance with the pressure in the atmospheric transfer chamber 12. In that case, N₂ gas heated during the cooling of the semiconductor wafer in the load lock container 34 is stored in the upper portion of the load lock container 34. The heated N₂ gas is actively discharged to the atmospheric channel 94 through the gas discharge port 92 formed at the ceiling portion 34B and new N₂ gas as a cooling gas is introduced. Therefore, the cooling efficiency can be further increased.

In this case, the pressure in the atmospheric transfer chamber 12 to which the heated cooling gas is discharged is set to a positive pressure slightly greater than the atmospheric pressure, as described above. Therefore, the pressure in the load lock container 34 is set to a pressure higher than the atmospheric pressure by the sum of the difference between the atmospheric pressure and the positive pressure and the operation pressure difference of the relief valve 96. Further, in the atmospheric pressure restoring process, the temperature of the semiconductor wafer W is measured by the thermocouple 98 provided at the supporting portion 52. When the measurement value is lower than or equal to a safe temperature, e.g., about 100° C., the opening operation restriction unit 100 outputs an opening operation permission signal to the system control unit 30. Then, the system control unit 30 stops the supply of N₂ gas by closing the opening/closing valve 84 of the gas introduction unit 72 and opens the gate valve G between the load lock container 34 and the atmospheric transfer chamber 12 to unload the semiconductor wafer W cooled to a temperature lower than or equal to about 100° C. as described above.

In this case, instead of providing the thermocouple 98 or the opening operation restriction unit 100, time required to cool the semiconductor wafer to a temperature lower than or equal to about 100° C., which is obtained in advance based on relationship between the temperature of the semiconductor wafer before cooling and the cooling gas supply time, may be stored as a parameter in the system control unit 30. By referring to this parameter, the supply stop of the cooling gas and the opening operation of the gate valve can be performed.

In accordance with the present embodiment, the load lock device, which is connected between the vacuum chamber and the atmospheric chamber through the gate valves and whose interior is selectively switchable between a vacuum atmosphere and an atmospheric pressure atmosphere, includes: the support unit 50 provided in the load lock container 34 and having the supporting portions 52 for supporting target objects, e.g., semiconductor wafers W, in multiple stages; and the gas introduction unit 72 having the gas ejection holes 74 which are provided so as to correspond to the supporting portions 52 and eject an atmosphere pressure restoring gas as a cooling gas. Therefore, when the target objects are unloaded to the atmospheric chamber, cooling efficiency can be increased to maintain a high throughput. Further, the target objects in multiple stages can be uniformly cooled without a temperature difference therebetween.

By further providing the atmospheric exhaust system 90 for exposing an atmosphere in the load lock container 34 to the outside, a heated cooling gas can be actively discharged from an upper portion of the load lock container 34 after the atmosphere in the load lock container 34 is returned to an atmospheric pressure. This can further increase the cooling efficiency.

In addition, by further providing the temperature measurement unit 98 at the supporting portions 52 and the opening operation restricting unit 100 for restricting an opening operation of the gate valve G between the load lock container 34 and the atmospheric chamber based on a measurement value of the temperature measurement unit 98, the gate valve can be opened after the target objects are cooled to a desired temperature, so that the safety can be increased.

### First Modification

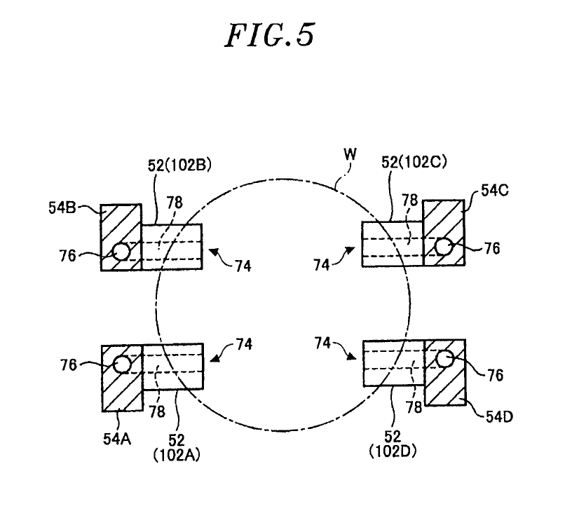

Hereinafter, a first modification of the load lock device of the present embodiment will be described. In the above-described embodiment, the shelf members 58A and 58B of the supporting portions 52 for supporting the semiconductor wafer W are bridged over the columns 54A and 54B and the columns 54C and 54D, respectively. However, it is not limited thereto, and rod members may be provided so as to correspond to the columns 58A to 58D. FIG. 5 is an enlarged view showing a cross section of a support unit of the first modification of the load lock device. In FIG. 5, like reference numerals will be given to the same parts as those described in FIGS. 1 to 4.

As described above, rod members 102A to 102D serving as the supporting portions 52 are horizontally provided so as to correspond to the columns 54A to 54D of the support unit 50, respectively. The semiconductor wafer W is supported by the rod members 102A to 102D such that the backside of the semiconductor wafer W contacts the top surfaces of the rod members 102A to 102D. In this case, the rod members 102A to 102D may be made of the same material as that of the shelf members 58A and 58B. Further, the gas nozzles 78 and the gas ejection holes 74 having the same configurations as those shown in FIG. 4 are formed in the rod members 102A to 102D so as to communicate with the gas inlet lines 76, so that a nonreactive gas, e.g., N₂ gas, serving as an atmospheric pressure restoring gas as a cooling gas can be ejected therefrom. The first modification can provide the same effects/advantages as those of the first embodiment.

### Second Modification

Hereinafter, a second modification of the load lock device of the present embodiment will be described. In the above-described embodiments, the gas nozzles 78 and the gas ejection holes 74 are formed in the supporting portions 52 configured as the shelf members 58A and 58B or the rod members 102A to 102D. However, the gas nozzles 78 and the gas ejection holes 74 may be formed at the columns 54A to 54D.

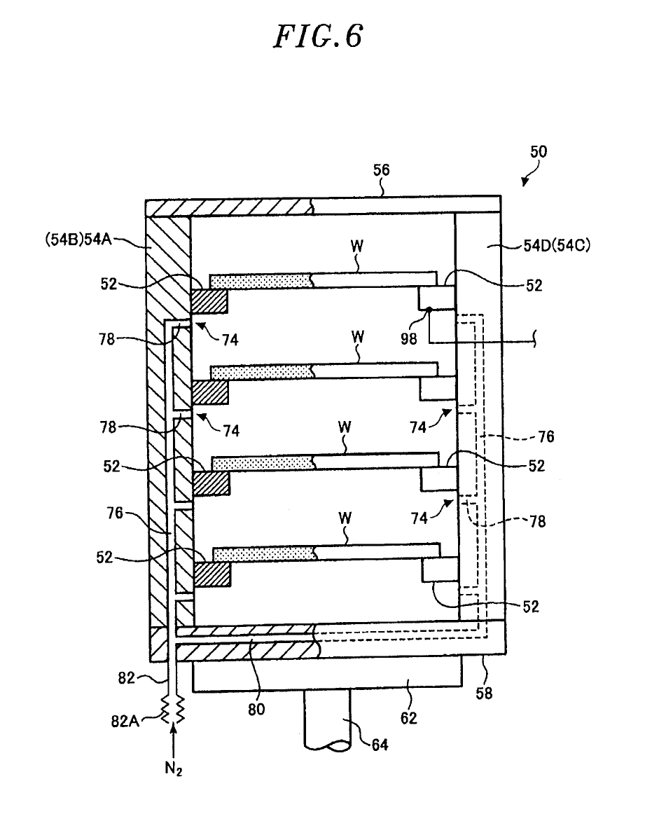

FIG. 6 is an enlarged partial cross sectional view showing a support unit of the second modification of the load lock device. In FIG. 6, like reference numerals will be given to the same parts as those described in FIGS. 1 to 5. As described above, the gas nozzles 78 and the gas ejection holes 74 communicating with the gas inlet lines 76 are formed in the columns 54A to 54D so as to be positioned below the supporting portions 52 configured as the shelf members 58A and 58B or the rod members 102A to 102D. Further, a nonreactive gas, e.g., N₂ gas, serving as an atmospheric pressure restoring gas as a cooing gas is ejected from the gas ejection holes 74.

The second modification can provide the same effects/advantages as those of the above-described embodiments. In the second modification, in order to introduce a large amount of N₂ gas, additional gas nozzles 78 and gas ejection holes 74 may be provided at different positions in the height direction of the columns 54A to 54D.

### Third Modification

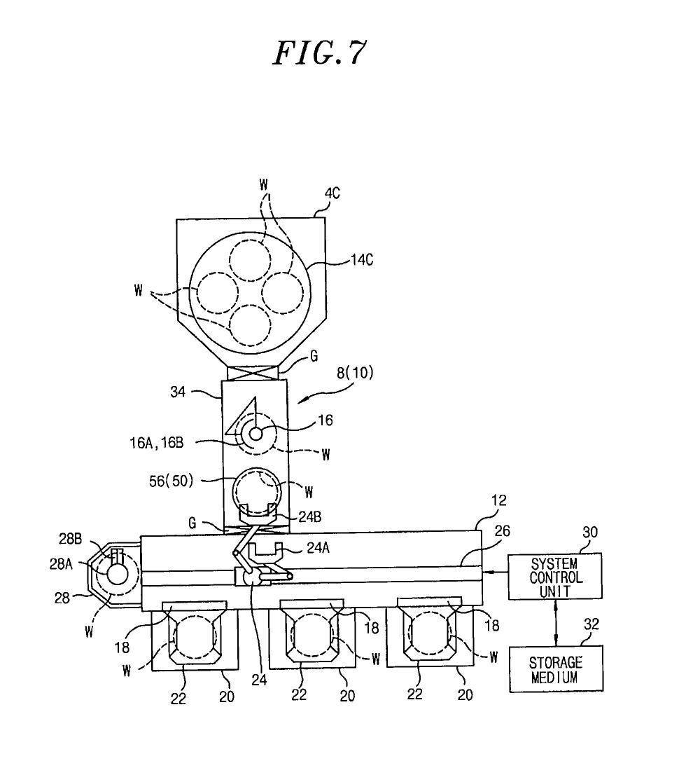

Hereinafter, a third modification of the load lock device of the present embodiment will be described. The above embodiment has described, as an example, the case in which the vacuum transfer chamber 6 as a vacuum chamber is connected to one side of the load lock device. However, the present invention is not limited thereto, and the processing chamber 4C as a vacuum chamber for performing a plurality of heat treatments simultaneously may be connected to one side of the load lock device. FIG. 7 is a schematic top view showing an example of a processing system including the third modification of the load lock device in accordance with the embodiment of the present invention. In FIG. 7, like reference will be given to the same parts as those described in FIGS. 1 to 6.

As described above, in this example, instead of the vacuum transfer chamber 6, the processing chamber 4C as a vacuum chamber is directly connected to one end of the load lock device 8 (10) via a gate valve G. As described above, in the processing chamber 4C, four semiconductor wafers W are simultaneously subjected to heat treatment under the vacuum atmosphere. In this case, the horizontal length of the load lock container 34 is set to be slightly greater than that in FIGS. 1 to 6, and the vacuum transfer mechanism 16 is disposed in series with the support unit 50 in the load lock container 34.

In this case, the vacuum transfer mechanism 16 has picks 16A and 16B vertically arranged at a lower and an upper stage, and is configured to be vertically movable. The semiconductor wafer W is transferred between the mounting table 14C in the processing chamber 4C and the support unit 50 in the load lock container 34 by using the vacuum transfer mechanism 16. In this case, any types of support units described in FIGS. 1 to 6 can be used as the support unit 50. The third modification can provide the same effects/advantages as those of the above-described embodiment.

Although the support unit 50 of the above-described embodiment has the four supporting portions 52 arranged in the vertical direction (the supporting portions 52 arranged in four stages), the number of the supporting portions 52 is not limited as long as it is plural. For example, since twenty-five semiconductor wafers can be accommodated in a single cassette container, the support unit 50 may have twenty-five supporting portions 52 (supporting portions 52 arranged in twenty-five stages). Further, the number of semiconductor wafers that can be simultaneously subjected to heat treatment in the processing chamber 4C is not limited to four. Preferably, the number of the supporting portions 52 is set to be equal to the number of semiconductor wafers that can be processed at a time in the processing chamber 4C.

In the above-describe embodiment, the gas inlet lines 76 are formed in the columns 54A to 54D of the support unit 50. However, it is not limited thereto, and a gas line forming the gas inlet lines 76 may be formed outside the columns 54A to 54D along the columns 54A to 54D.

In the above embodiment, the semiconductor wafer is used as an example of the target object. However, the semiconductor wafer may include a silicon substrate, and a compound semiconductor substrate such as GaAs, SiC, GaN or the like. Further, the present invention may also be applied to another substrate such as a glass substrate for a liquid crystal display, a ceramic substrate or the like.

This application claims priority of Japanese Patent Application No. 2009-199103, filed on Aug. 29, 2009, the entire contents of which are incorporated herein by reference.

What is claimed is:

1. A load lock device adapted to be connected between a vacuum chamber and an atmospheric chamber through gate valves, the interior of the load lock device being selectively switchable between a vacuum atmosphere and an atmospheric pressure atmosphere, the load lock device comprising:
a load lock container;
a support unit provided in the load lock container and having supporting portions for supporting target objects in multiple stages;
a gas introduction unit having gas ejection holes which are provided so as to correspond to the supporting portions and eject as a cooling gas a restoring gas for restoring the atmosphere in the load lock container to the atmospheric pressure; and
a vacuum exhaust system for evacuating the atmosphere in the load lock container to vacuum.

2. The load lock device of claim 1, wherein the support unit has a plurality of upright columns, and the supporting portions are provided at the columns at a predetermined pitch.

3. The load lock device of claim 1, wherein the gas introduction unit has gas inlet lines formed in the support unit.

4. The load lock device of claim 1, wherein the support unit is installed on a vertically movable elevation plate.

5. The load lock device of claim 1, wherein each of the supporting portions has shelf members which come into contact with a backside of the target object.

6. The load lock device of claim 1, wherein each of the supporting portions has rod members which come into contact with a backside of the target object.

7. The load lock device of claim 1, further comprising an atmospheric exhaust system for exposing the atmosphere in the load lock container to the outside.

8. The load lock device of claim 7, wherein a gas discharge port of the atmospheric exhaust system is provided at an upper portion of the load lock container.

9. The load lock device of claim 7, wherein the atmospheric exhaust system has a relief valve which is opened to communicate with the outside when a pressure in the load lock container becomes higher than a predetermined pressure.

10. The load lock device of claim 7, wherein the atmospheric exhaust system has a relief valve which is opened to communicate with the atmospheric chamber when a pressure in the load lock container becomes higher than a predetermined pressure.

11. The load lock device of claim 1, wherein the atmospheric chamber is maintained at a positive pressure slightly greater than the atmospheric pressure.

12. The load lock device of claim 1, further comprising:
a temperature measurement unit provided at the supporting portions; and
an opening operation restriction unit for restricting an opening operation of a gate valve between the load lock container and the atmospheric chamber based on a measurement value of the temperature measurement unit.

13. The load lock device of claim 1, wherein the support unit is made of one or more materials selected from a group consisting of ceramic, quartz, metal and heat resistant resin.

14. The load lock device of claim 1, wherein the load lock container has therein a transfer mechanism which is extensible, contractible and rotatable to transfer the target object.

15. A processing system comprising:
a vacuum chamber connected to a processing chamber for performing heat treatment on a plurality of target objects at a time, the vacuum chamber serving as a vacuum transfer chamber having therein a vacuum transfer mechanism for transferring the target objects;
an atmospheric chamber whose interior is maintained at or around an atmospheric pressure, the atmospheric chamber serving as an atmospheric transfer chamber including therein an atmospheric transfer mechanism for transferring the target objects to load or unload the target objects with respect to atmospheric side; and
the load lock device described in claim 1, provided between the vacuum chamber and the atmospheric chamber.

16. A processing system comprising:
a vacuum chamber serving as a processing chamber for performing heat treatment on a plurality of target objects at a time;
an atmospheric chamber whose interior is maintained at or around an atmospheric pressure, the atmospheric chamber serving as an atmospheric transfer chamber including therein an atmospheric transfer mechanism for transferring the target objects to load or unload the target objects with respect to atmospheric side; and
the load lock device described in claim 14, provided between the vacuum chamber and the atmospheric chamber.
